(19) United States
(12) Patent Application Publication
(10) Pub. No.: US 2025/0324679 A1
(43) Pub. Date: Oct. 16, 2025

(54) VERTICAL JFET SEMICONDUCTOR DEVICES WITH LOCALIZED AVALANCHE BREAKDOWN

(71) Applicant: Wolfspeed, Inc., Durham, NC (US)

(72) Inventors: Rahul R. Potera, Apex, NC (US); Sei-Hyung Ryu, Cary, NC (US)

(21) Appl. No.: 18/633,687

(22) Filed: Apr. 12, 2024

(51) Int. Cl. H01L 29/06; H01L 29/16; H01L 29/808

(52) U.S. Cl. CPC H10D 62/108; H10D 30/831; H10D 62/107; H10D 62/126; H10D 62/8325

(57) ABSTRACT

A semiconductor device includes an active region comprising first and second mesa stripes and a trench between the mesa stripes. The trench has a first width between the first and second mesa stripes near a central portion of the first and second mesa stripes and a second width between the first and second mesa stripes near end portions of the first and second mesa stripes. The second width is less than the first width.

### FIELD

The present disclosure relates to semiconductor devices and, more particularly, to power semiconductor devices having gate resistors.

### BACKGROUND

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. A conventional silicon carbide-based power semiconductor device typically has a silicon carbide substrate, such as a silicon carbide wafer having a first conductivity type (e.g., an n-type substrate), on which a silicon carbide epitaxial layer structure is formed which may have both first and second conductivity type layers and/or regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

The epitaxial layer structure of most power semiconductor devices includes a drift region and an “active region” that is formed on and/or in the drift region. The active region acts as a main junction for blocking voltage during off-state operation (also referred to as “reverse bias” or “reverse blocking” operation) and current flows through the active region during on-state operation (also referred to as “forward bias” operation). Most power semiconductor devices also have an edge termination region adjacent the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A vertical JFET is a three terminal device that has gate, drain and source terminals that are formed on a semiconductor layer structure, which typically comprises a semiconductor substrate with epitaxial layers formed thereon. Source regions that are electrically connected to the source terminal and a drain region that is electrically connected to the drain terminal may be formed in the semiconductor layer structure. A plurality of channel regions are interposed in the semiconductor layer structure between the source regions and the drain region. A gate structure of the vertical JFET may include, for example, a gate bond pad that serves as the gate terminal, a gate pad that is connected to the gate bond pad, a plurality of gate contacts, and one or more gate buses and/or gate contacts that electrically connect the gate pad to the gate contacts. The gate contacts are disposed adjacent the respective channel regions. Power JFETs are typically normally-on devices, meaning that a JFET conducts current when a voltage of 0 volts is applied to the gate structure.

### SUMMARY

A semiconductor device according to some embodiments includes an active region comprising first and second mesa stripes and a trench between the mesa stripes. The trench has a first width between the first and second mesa stripes near a central portion of the first and second mesa stripes and a second width between the first and second mesa stripes near end portions of the first and second mesa stripes. The second width is less than the first width.

The first mesa stripe may have a first width near the central portion of the first mesa stripe and a second width near the end portions of the first mesa stripe, wherein the second width is greater than the first width.

In some embodiments, the first mesa stripe increases in width from the first width to the second width near the end portions of the first mesa stripe.

In some embodiments, the first mesa stripe increases in width linearly from the first width to the second width near the end portions of the first mesa stripe.

In some embodiments, the trench tapers in width from the first width to the second width near the end portions of the first and second mesa stripes.

The end portions of the first and second mesa stripes may be separated from the central portions of the first and second mesa stripes by second trenches.

The semiconductor device may further include a source metallization that contacts the central portions of the first and second mesa stripes and does not contact the end portions of the first and second mesa stripes.

The central portions of the first and second mesa stripes may have a first channel doping and the end portions of the first and second mesas may have a second channel doping that is greater than the first channel doping.

The first and second mesa stripes may include sidewall gate regions having a first conductivity type and channel regions between the sidewall gate regions, the channel regions have the first channel doping in central portions of the mesa stripes and the second channel doping in the end portions of the mesa stripes.

The second channel doping may be selected to preferentially induce unclamped inductive switching (UIS) breakdown near the end portions of the mesa stripes before UIS breakdown occurs near the central portions of the mesa stripes under voltage blocking conditions.

A semiconductor device according to further embodiments includes an active region comprising first and second mesa stripes and a first trench between the mesa stripes, wherein the first trench has a first width between the first and second mesa stripes, and first and second dummy mesas adjacent respective first and second ends of the first and second mesa stripes. The first and second dummy mesas define a second trench between the first and second dummy mesas. The second trench has a second width between the first and second dummy mesas that is less than the first width.

The first and second mesa stripes may each have a first width, and the first and second dummy mesas may each have a second width that is greater than the first width.

The semiconductor device may further include a source metallization that contacts the first and second mesa stripes and does not contact the dummy mesas.

The first and second mesa stripes may have a first channel doping and the first and second dummy mesas may have a second channel doping that is greater than the first channel doping.

The first and second mesa stripes and the first and second dummy mesas may include sidewall gate regions having a first conductivity type and have channel regions having a second conductivity type between the sidewall gate regions, wherein the channel regions in the first and second mesa stripes have the first channel doping in the channel regions thereof and the first and second dummy mesas have the second channel doping in the channel regions thereof.

The second channel doping is selected to preferentially induce UIS breakdown near the end portions of the mesa stripes before UIS breakdown occurs near the central portions of the mesa stripes.

A semiconductor device according to further embodiments includes an active region comprising first and second mesa stripes and a trench between the mesa stripes, and a channel doping in the first and second mesa stripes, wherein the channel doping is higher near end portions of the first and second mesa stripes than near central portions of the first and second mesa stripes.

The first and second mesa stripes comprise sidewall gate regions having a first conductivity type and channel regions between the sidewall gate regions, wherein the channel regions have the first channel doping in central portions of the mesa stripes and the second channel doping in the end portions of the mesa stripes.

The second channel doping may be selected to preferentially induce UIS breakdown near the end portions of the mesa stripes before UIS breakdown occurs near the central portions of the mesa stripes under voltage blocking conditions.

A semiconductor device according to further embodiments includes an active region comprising a plurality of alternating mesa stripes and trenches, wherein each of the mesa stripes extends in a first direction and has a width in a second direction that is perpendicular to the first direction, and an edge termination region adjacent to the active region, wherein the edge termination region may include a plurality of alternating mesa rings and trench rings. A width of a first mesa ring in the edge termination region is larger than the width of the mesa stripes.

The width of the first mesa ring may be selected to preferentially induce UIS breakdown near the first mesa ring before UIS breakdown occurs near the mesa stripes under voltage blocking conditions.

The width of the first mesa ring in the edge termination region may be about 1% to about 20% larger than the width of the mesa stripes. In some embodiments, the width of the first mesa ring in the edge termination region may be about 5% to about 15% larger, and in some embodiments about 8% to 12% larger, than the width of the mesa stripes.

The semiconductor device may include a vertical junction field effect transistor, and wherein the plurality of mesa stripes and trenches are formed in a semiconductor layer having a first conductivity type, the plurality of mesas comprising sidewall gate regions having a second conductivity type in sidewalls of the plurality of mesas and first conductivity type channel regions between the sidewall gate regions, the semiconductor device further comprising second conductivity type gate contact regions beneath the plurality of trenches and second conductivity type guard rings beneath the trench rings.

A spacing between the guard rings in the edge termination region may be about 0.1 microns or 0.2 microns larger than an optimum guard ring spacing needed for a desired blocking voltage.

### BRIEF DESCRIPTION OF DRAWINGS

FIG. 1 illustrates a cell of a vertical JFET semiconductor device.

FIG. 2 illustrates, in plan view, conventional layouts of vertical JFET semiconductor devices.

FIG. 3 illustrates, in plan view, portions of a layout of a vertical JFET device according to some embodiments.

FIG. 4 is a cross-sectional diagram of portions of the vertical JFET device of FIG. 3.

FIGS. 5A and 5B illustrate, in plan view, portions of a layout of a vertical JFET device according to some embodiments.

FIG. 6 is a cross-sectional diagram of portions of the vertical JFET device of FIGS. 5A and 5B.

FIG. 7 illustrates, in plan view, portions of a layout of a vertical JFET device according to some embodiments.

FIG. 8 is a cross-sectional diagram of portions of the vertical JFET device of FIG. 7.

FIG. 9 is a plan view of a portions of a vertical JFET according to some embodiments.

FIG. 10 is a cross-sectional view of a portions of the vertical JFET of FIG. 9.

### DETAILED DESCRIPTION

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Although some embodiments are described in the context of a silicon carbide JFET device, it will be appreciated that aspects of the inventive concepts may be applicable to other types of devices, such as MOSFETs, insulated gate bipolar transistors (IGBTs) and other types of devices.

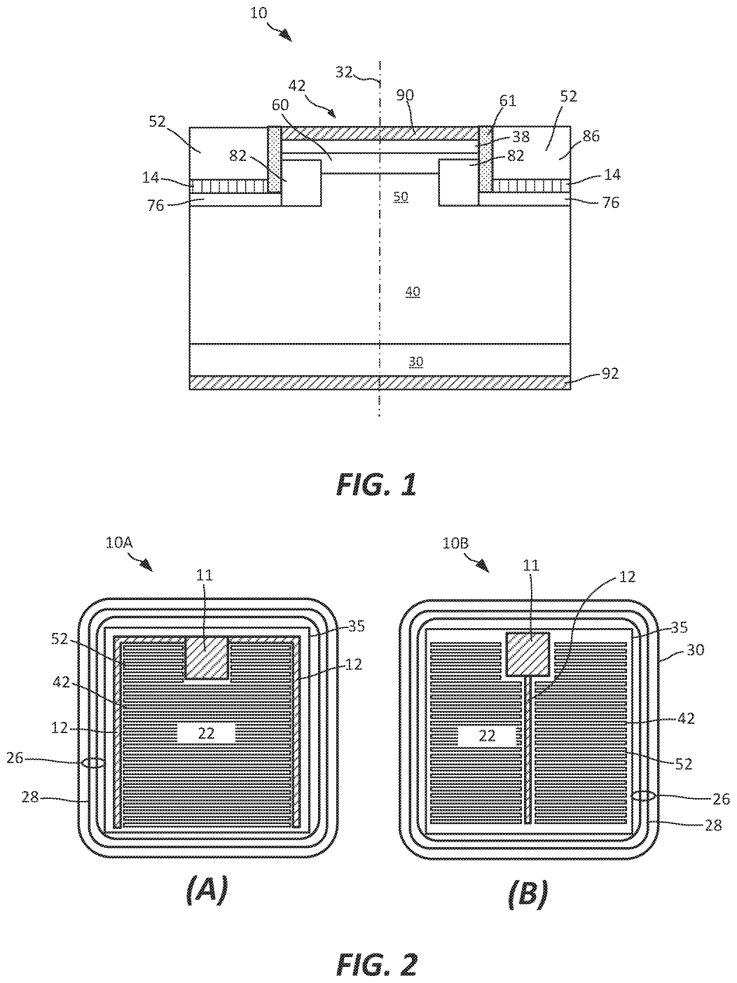

An n-channel vertical JFET structure 10 is shown in FIG. 1. The vertical JFET structure 1 includes an n+ substrate 30 on which an n-drift layer 40 is formed. An n-type channel region 50 is on the drift layer 40, and an n+ source layer 60 is on the channel region 50. An n++ source contact layer 38 is on the n+ source layer 60. A drain ohmic contact 92 is on the substrate 30, and a source ohmic contact 90 is on the source contact layer 38. The channel region 50, source layer 60 and source contact layer 38 are provided as part of a mesa 42 above the drift layer 40. Trenches 52 are formed in the structure 10 adjacent the mesa 42.

A p+ gate region 82 is provided as part of the mesa 42 adjacent the channel region 50. A p++ gate contact region 76 is provided adjacent the gate region 82, and a gate ohmic contact 14 is formed on the gate contact region 76 in the trenches 52 on opposite sides of the mesa 42. To form the gate ohmic contact 14, a layer of metal, such as nickel (Ni), is deposited on the upper surfaces of the gate contact regions 76 and patterned appropriately. The metal is then annealed (for example, by being subjected to high temperature for a period of time) to form metal silicide layers on the upper surfaces of the gate contact regions 76, which provide ohmic contacts to the underlying layers.

An insulation layer 86 is formed in the trenches 52 on the gate ohmic contact 14 and the gate contact region 76. The insulation layer 86 may be formed from silicon oxide. Oxide/nitride spacer layers 61 are provided on sidewalls of the mesa 42.

The vertical JFET unit cell structure 10 is symmetrical about the axis 32 and includes two gate regions 82 as part of the mesa 42 on opposite sides of the channel region 50.

The channel of the vertical JFET structure 10 is formed within the mesa 42 between the gate regions 82. The channel width is into the plane of FIG. 1, and the channel length is in the vertical direction from the source region 60 to the drift layer 40. Such a vertical JFET structure with a short channel length may also be called a static-induction transistor (SIT). In a SIT, the channel length is chosen based on a trade-off between low on-resistance in the on-state (short channel) and resistance to drain-induced barrier lowering (DIBL) in the off-state. A p-channel JFET may have a similar structure, but the conductivity types are reversed from those shown in FIG. 1.

In operation, conductivity between the source layer 60 and the substrate 30 is modulated by applying a reverse bias to the gate regions 82 relative to the source layer 60. To switch off an n-channel device such as the JFET structure 10, a negative gate-to-source voltage (or gate voltage) V_{GS} is applied to the gate regions 82. When no voltage is applied to the gate region 82, charge carriers can flow freely from the source layer 60 through the channel region 50 and the drift layer 40 to the substrate 30.

FIG. 2 illustrates, in plan view, conventional layouts of vertical JFET semiconductor devices 10A and 10B. Referring to FIG. 2(A), a JFET device 10A is formed on a substrate 30. The device 10A includes an active region 22 in which a plurality of alternating mesas 42 and trenches 52 are formed. The active region 22 is surrounded by an edge termination region 26 in which a plurality of guard rings 28 are formed. Guard rings 28 are shown as an example of an edge termination for a power semiconductor device. However, other termination structures, such as field rings, junction termination extension (JTE) regions, etc., can be provided in the edge termination region 26.

A silicide region 35 is formed on an upper surface of the device within the active region 22 in areas other than on the mesas 42. The silicide region 35 forms the gate ohmic contacts 14 within the trenches 52. A gate contact pad 11 is formed on the upper surface of the device 10A within the silicide region 35, and a pair of gate buses 12 (also referred to as gate runners 12) extend from the gate contact pad 11 around the outer periphery of the active region 22 adjacent the ends of the mesas 42 and trenches 52 of the device 10A. The gate contact pad 11 and the gate buses 12 may include a conductive material such as a metal silicide and/or a metal layer.

The silicide region 35 provides a low resistance current path between the gate buses 12/gate contact pad 11 and the gate ohmic contacts 14 (FIG. 1) that are formed within the trenches 52.

The JFET device 10B shown in FIG. 2(B) is similar to the JFET device 10A shown in FIG. 2(A), except that the JFET device 10B includes only a single gate bus 12 which extends from the gate contact pad 11 through the center of the active region 22.

In both JFET devices 10A, 10B, a gate voltage applied to the gate contact pad 11 is conducted through the gate bus 12 and silicide region 35 to the gate ohmic contacts 14 within the trenches 52.

In a switching power device such as a JFET device, a phenomenon referred to as unclamped inductive switching (UIS) may occur when the device is placed under high reverse bias. UIS occurs when current undesirably flows from the drain of the device back through the gate of the device. This subjects the device simultaneously to high current and high voltage, which dissipates a high amount of power in the device and may cause the device to fail when the UIS current exceeds a threshold limit. The ability to handle UIS current is an important quality of a switching power device.

If UIS current is limited by current crowding and filamentation in a part of the semiconductor structure, UIS weakness can be addressed by making the junction breakdown more uniform so that heat is dissipated more uniformly across the device. If UIS current is limited by the current carrying regions outside the semiconductor device, UIS weakness can be addressed by increasing ampacity at those choke points.

When UIS current is not limited in those ways, then gate-drain UIS current causes a voltage drop across the gate resistance, which biases the gate of the device. At sufficient UIS current, this UIS-induced gate bias can exceed the local threshold voltage (VT) of the device and turn on the channel locally (i.e., in the vicinity of the induced gate bias). The channel current induced by UIS biasing will heat up the device locally creating a hotspot in the device. This further reduces VT and increases leakage near the hotspot. This condition creates a positive feedback loop, referred to as a thermal runaway condition, that can cause the device to fail catastrophically at the hotspot.

UIS capability is an important feature of a switching power device and is typically increased by addressing the key limiting factors of UIS rating. If limited by current crowding and filamentation in a part of the semiconductor, UIS weakness can be addressed by making junction breakdown more uniform so that heat is dissipated more uniformly across the device. In case of vertical JFETs when high UIS currents flow through the device to the gate pad, intrinsic gate regions can get biased up to open the JFET channel. Heating from such channel current can cause positive feedback by further reducing threshold voltage and increasing channel current, thereby causing current filamentation and hotspot induced device failure.

Some embodiments described herein provide designs that may improve the UIS capability of a SiC JFET by localizing breakdown to regions where current flow will not debias the gate and open the channel of the device.

In previous technology, as shown in FIG. 2, UIS current in the vertical JFET runs through drain-gate junction in the active area, through silicided trench regions to the gate bus and onwards through metalized gate bus to the gate pad.

According to some embodiments, the width of mesas in the device is increased near the ends of the device. In the wider portions of the mesas, there will be a larger spacing between p+ gate bottom regions, leading to more field concentration in blocking mode, and thereby breaking down at a lower voltage than in the active area.

In some embodiments, dummy mesas regions are added at the ends of the source mesas in the active area, with larger width than width of source mesas. As noted above, wider dummy mesas will have larger spacing between p+ gate bottom regions, leading to more field concentration in blocking mode, and thereby breaking down at a lower voltage than in the active area.

In a semiconductor device according to some embodiments, UIS current may preferentially flow through the trench bottoms at the ends of the mesas and on to the gate runner and gate pad. Most of the intrinsic gate resistance will be in the silicided gate trench bottoms, and UIS current in this design will bypass that gate resistance, thereby not debiasing the gate significantly and not turning on the channel. Channel current has positive feedback with temperature, leading to hotspot failures. Drain-gate UIS current has negative feedback with temperature, which will not lead to hotspotting. This design reduces hotspotting and increases UIS capability of the JFET up to what can be handled by gate runner metallization. Designs according to some embodiments will be most effective when there is little resistance between localized avalanche locations and the gate pad.

One drawback of this design is that a small amount of active area may be lost to the wider mesa structures at ends of JFET mesas.

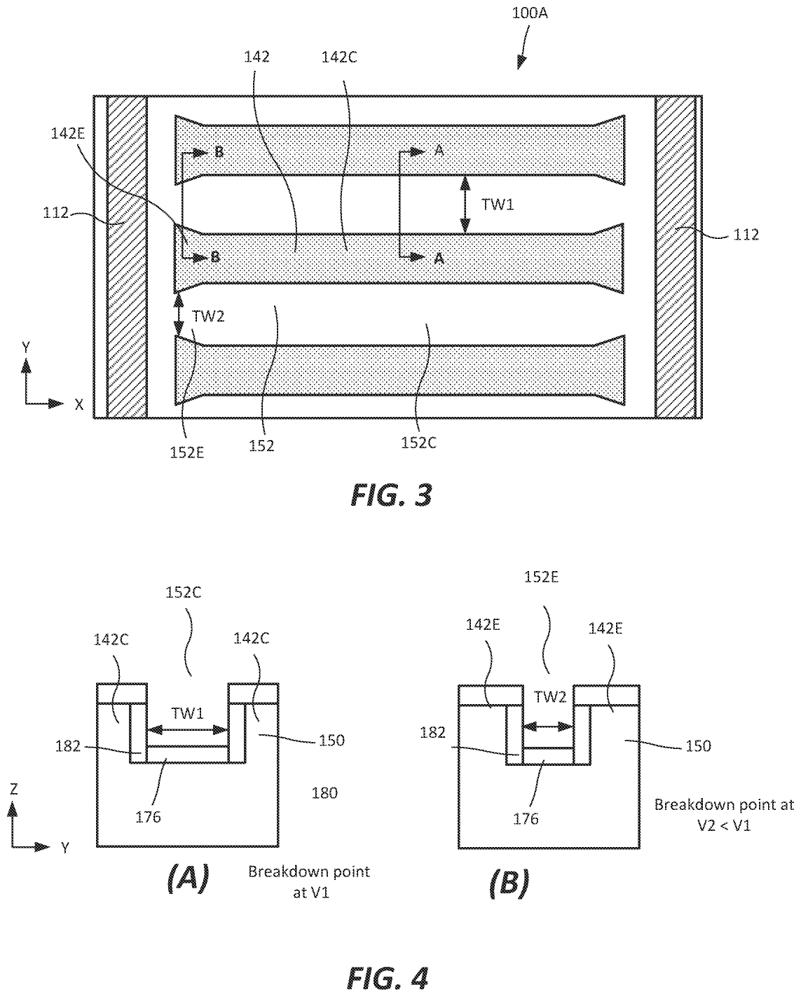

FIG. 3 illustrates, in plan view, portions of a layout of a vertical JFET device 100A according to some embodiments, and FIG. 4 is a cross-sectional diagram of portions of the vertical JFET device 100A of FIG. 3 taken along sections A-A (FIG. 4(A)) and B-B (FIG. 4B)), respectively.

In particular, FIG. 3 illustrates a portion of the active region of a vertical JFET device 100A including alternating mesa stripes 142 and trenches 152 between the mesa stripes 142. The mesa stripes 142 and trenches 152 extend lengthwise in a first direction (e.g., the X-direction as shown in FIG. 3), and have widths in a second direction that is perpendicular to the first direction (e.g., the Y-direction as shown in FIG. 3).

Gate buses 112 run adjacent to the ends of the mesa stripes 142 and trenches 152 for supplying a gate signal to the gate ohmic contacts within the trenches 152. Each of the mesa stripes 142 includes a central portion 142C and opposing end portions 142E at respective ends of the mesa stripes 142. Likewise, each of the trenches 152 includes a central portion 152C and opposing end portions 152E at respective ends thereof.

In this embodiment, each mesa stripe 142 widens near the end portions 142E thereof so that the trench 152 is tapered near respective ends thereof. That is, the mesa stripes 142 have mesa widths MW1 near the centers thereof and mesa widths MW2 near the ends thereof, where MW2>MW1. Similarly, each trench 152 tapers near the end portions 152E thereof. That is, the trenches 152 have trench widths TW1 near the centers thereof and trench widths TW2 near the ends thereof, where TW2<TW1. The mesa width MW1 near the centers of the mesa stripes 142 may be about 1.2 microns to about 1.5 microns, and the mesa width MW2 near the ends of the mesa stripes 142 may be about 1.5 microns to about 2 microns. The tapering of the trenches 152/widening of the mesa stripes 142 near the end portions 142E of the mesa stripes 142 may occur in a linear fashion as generally illustrated in FIG. 3 in some embodiments. Alternatively, in some embodiments, the tapering of the trenches 152/widening of the mesa stripes 142 near the end portions 142E of the mesa stripes 142 may occur in a non-linear fashion, such as in a stepwise fashion.

As shown in FIGS. 4(A) and 4(B), the width of the JFET channel region 150 in each mesa stripe 142 widens in cross-section where the trench 142 is tapered. This causes the electric field at the bottom corners of the p-type regions at the bottom of the trench 142 (i.e., the gate contact regions 76 and gate regions 82 shown in FIG. 1) to be higher in breakdown conditions. Thus, breakdown is initiated at the widened end portions 142E of the mesa stripes 142, and UIS current may flow preferentially between the widened end portions 142E of the mesas and the gate bus 112, which may lead to less biasing-up of the intrinsic gate during UIS and less chance of hotspotting, because the intrinsic gate resistance (RG) at these locations is lower than at locations further from gate bus 112. Additionally, if hotspotting happens, there is more heat spreading possible at the ends of the mesa stripes 142, so the hotspotting effect may be slowed down.

The trade-off with the design shown in FIGS. 3 and 4 is that the threshold voltage (V_{T}) at the ends of the mesa stripes 142 will be about 2V lower if the mesa stripe 142 is flared out by 0.1 μm in width. This will impact low current V_{T} and introduce a kink in the transconductance curve, such that the device will need a gate-to-source voltage (V_{GS}) about 2V lower VGS to keep the device turned off.

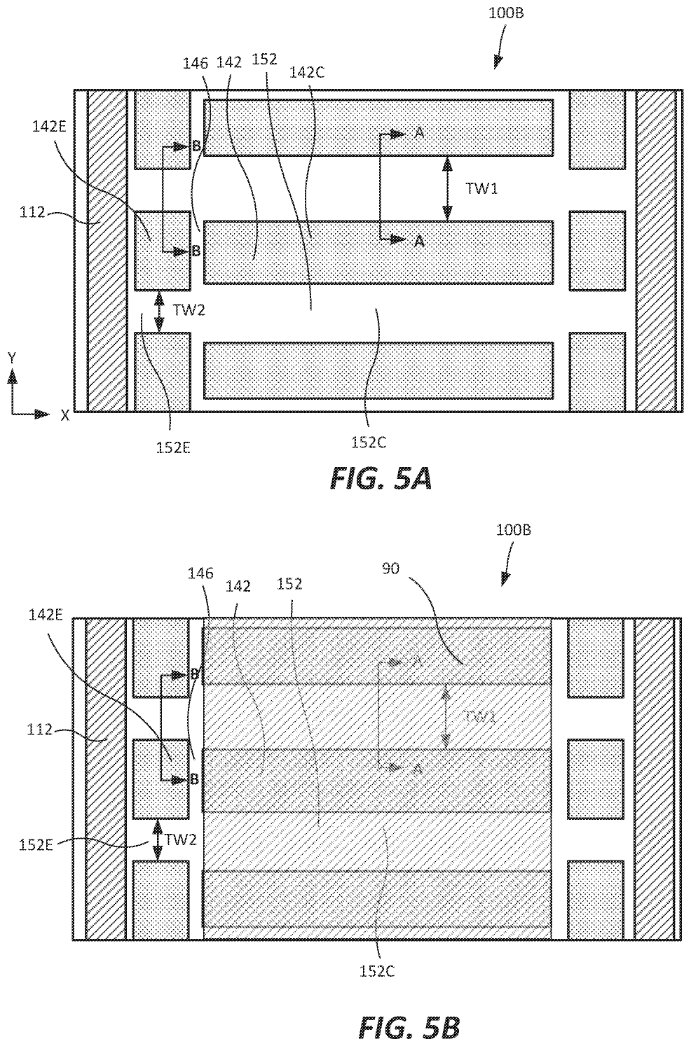

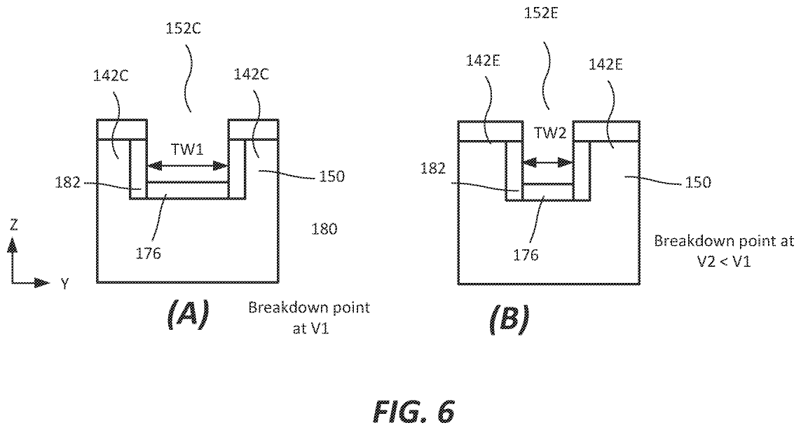

FIGS. 5A and 5B illustrate, in plan view, portions of a layout of a vertical JFET device 100B according to some embodiments, and FIG. 6 is a cross-sectional diagram of portions of the vertical JFET device 100B of FIG. 5A taken along sections A-A (FIG. 6(A)) and B-B (FIG. 6B)), respectively.

In particular, FIG. 5A illustrates a portion of the active region of a vertical JFET device 100A including alternating mesa stripes 142 and trenches 152 between the mesa stripes 142. Gate buses 112 run adjacent to the ends of the mesa stripes 142 and trenches 152 for supplying a gate signal to the gate ohmic contacts within the trenches 152. Each of the mesa stripes 142 includes a central portion 142C and opposing end portions 142E at respective ends of the mesa stripes 142. Likewise, each of the trenches 152 includes a central portion 152C and opposing end portions 152E at respective ends thereof. In the embodiment shown in FIG. 5, the end portions 142E of the mesa stripes 142 are separated from the central portions of the mesa stripes 142 by trenches 146. Additionally, as shown in FIG. 5B, the source contact 90 of the device does not contact the end portions 142E of the mesa stripes 142, so that the end portions of the mesa stripes 142 are electrically floating and do not participate in the on-state current flow of the device 100B.

In this embodiment, the central portions 142C of the mesa stripes 142 have mesa widths MW1 and the end portions 142E of the mesa stripes 142 have mesa widths MW2, where MW2>MW1. Similarly, central portions 152C of the trenches 152 have trench widths TW1 and the end portions 152E of the trenches 152 have trench widths TW2, where TW2<TW1.

Stated differently, in the embodiments illustrated in FIGS. 5A, 5B and 6, dummy mesa stripes 142E are formed adjacent to ends of active mesa stripes 142C and are separated from the active mesa stripes 142C by trenches 146. The active mesa stripes 142C have mesa widths MW1 and the dummy mesa stripes 142E have mesa widths MW2, where MW2>MW1. Similarly, active trenches 152C between the active mesas 152C have trench widths TW1, and the trenches 152E between the dummy mesa stripes 142E have trench widths TW2, where TW2<TW1.

Additionally, as shown in FIG. 5B, the source contact 90 of the device does not contact the dummy mesa stripes 142E, so that the dummy mesa stripes 142E are electrically floating and do not participate in the on-state current flow of the device 100B.

Because the dummy mesa stripes 142E are wider than the active mesa stripes 142C in the active area of the device 100B, during voltage blocking conditions there will be a higher electric field at bottom corners of the dummy mesa stripes 142E than at the corners of active mesa stripes 142C. This means that the dummy mesa stripes 142E will breakdown at a voltage that is less than the voltage at which the active mesa stripes 142C will break down. When breakdown occurs, UIS current will flow through the implanted gate regions 182 at the bottom corners of the dummy mesa stripes 142E and into the metalized gate runner 112 and gate pad 11.

Since no significant UIS current will flow through the silicided trench bottoms of the trenches 152C which have significant resistance, the gate of the device 100B will not be sufficiently debiased to open the drain-source channel 150. Mesa-tops of dummy mesa stripes 142E are electrically floating and not connected to the source metallization, so being wider will reduce the pinch-off voltage of the dummy mesa stripes 142E but it will not reduce the threshold voltage (V_{T}) of the JFET device 100B.

The active mesa stripes 142C may be about 1.2 microns to about 1.5 microns wide, and the floating mesa stripes 142E may be about 1.5 microns to about 2 microns wide. An upper limit of the width of the floating mesa stripes 142E may be determined based on how much lower the breakdown voltage (BV) can be compared to the breakdown of the active mesa stripes 142C.

In will be appreciated, that the corners of mesa stripes 142C, 142E of the device 100B maybe rounded to reduce field crowding.

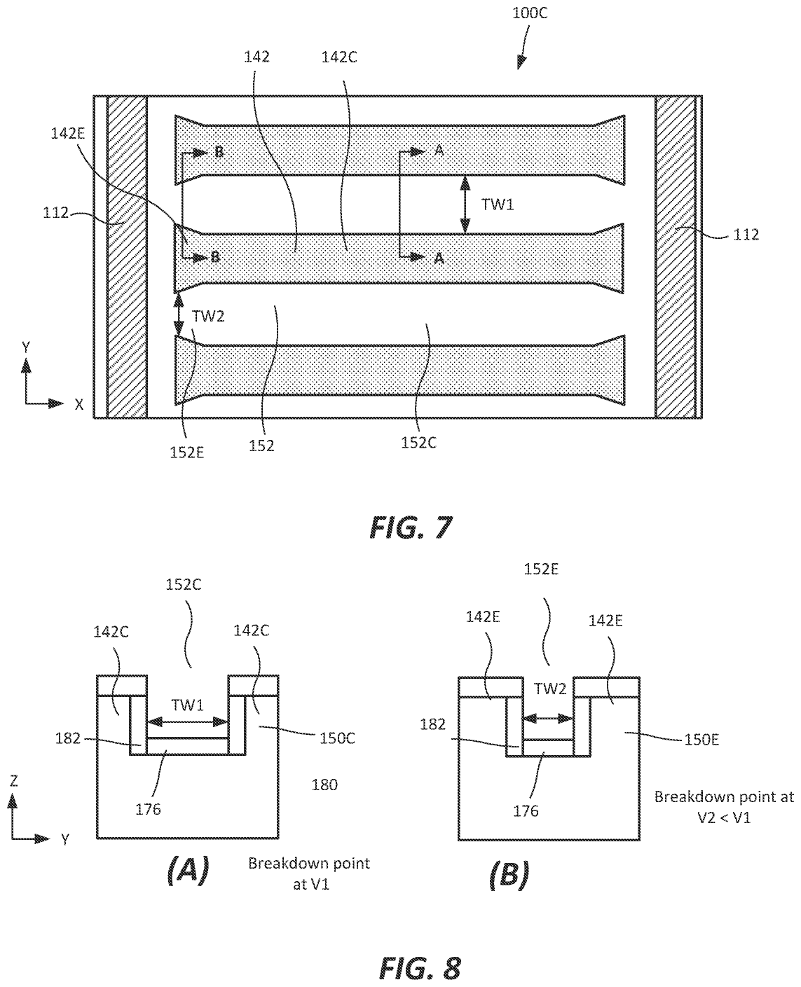

FIG. 7 illustrates, in plan view, portions of a layout of a vertical JFET device according to some embodiments taken along sections A-A (FIG. 8(A)) and B-B (FIG. 8B)), respectively.

In particular, FIG. 7 illustrates a portion of the active region of a vertical JFET device 100C including alternating mesa stripes 142 and trenches 152 between the mesa stripes 142. Gate buses 112 run adjacent to the ends of the mesa stripes 142 and trenches 152 for supplying a gate signal to the gate ohmic contacts within the trenches 152. Each of the mesa stripes 142 includes a central portion 142C and opposing end portions 142E at respective ends of the mesa stripes 142. Likewise, each of the trenches 152 includes a central portion 152C and opposing end portions 152E at respective ends thereof.

In this embodiment, each mesa stripe 142 widens near the end portions 142E thereof so that the trench 152 is tapered near respective ends thereof. That is, the mesa stripes 142 have mesa widths MW1 near the centers thereof and mesa widths MW2 near the ends thereof, where MW2>MW1. Similarly, each trench 152 tapers near the end portions 152E thereof. That is, the trenches 152 have trench widths TW1 near the centers thereof and trench widths TW2 near the ends thereof, where TW2<TW1. The mesa width MW1 near the centers of the mesa stripes 142 may be about 1.2 microns to about 1.5 microns, and the mesa width MW2 near the ends of the mesa stripes 142 may be about 1.5 microns to about 2 microns.

Referring to FIG. 8, in addition to the widening of the mesas 142, the channel regions 150E in the end portions 142E of the mesa stripes 142 have higher doping concentrations than the channel regions 150C in the center portions 142C of the mesa stripes 142. For example, the channel regions 150C in the center portions 142C of the mesa stripes 142 may be doped with n-type dopants at a concentration of about 5E16 cm-3, while the channel regions 150E in the end portions 142E of the mesa stripes 142 may be doped with n-type dopants at a concentration greater than about 5E16 cm-3. For example, the channel regions 150E in the end portions 142E of the mesa stripes 142 may be doped with n-type dopants at a concentration of about 8E16 cm-3. The increased channel doping in the channel regions 150E in the end portions 142E of the mesa stripes 142 may cause the end portions 142E of the mesa stripes 142 to be preferential breakdown sites. Thus, when breakdown occurs, UIS current will flow through the implanted gate regions 182 at the bottom corners of the dummy mesa stripes 142E and into the metalized gate runner 112 and gate pad 11.

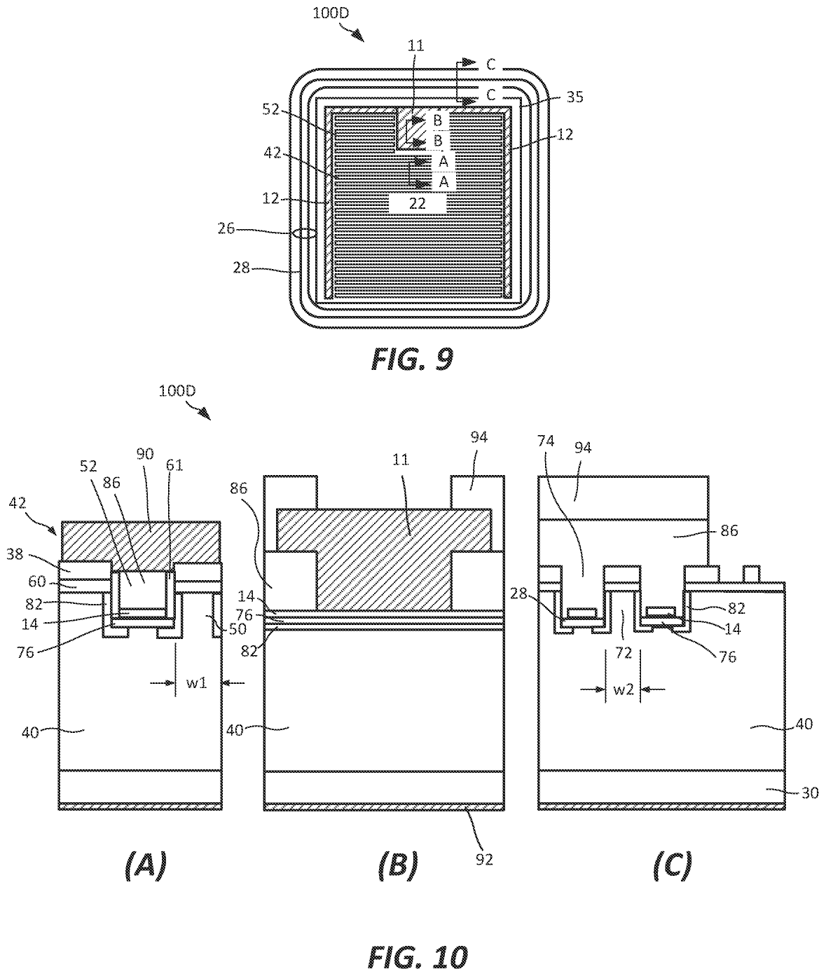

FIG. 9 is a plan view and FIG. 10 is a cross-sectional view of a portions of a vertical JFET 100D according to some embodiments. In particular, FIG. 10(A) is a cross-sectional view of a portion of the active region 22 of the device 100D taken along line A-A of FIG. 9, FIG. 10(B) is a cross-sectional view of a portion of the gate pad 11 of the device 100D taken along line B-B of FIG. 9, and FIG. 10(C) is a cross-sectional view of a portion of the edge termination region 26 of the device 100D taken along line C-C of FIG. 9.

As shown in FIG. 10(A), the mesas 42 in the active region 22 have a first width w1. The termination region 26 includes a plurality of alternating mesa rings 72 and trench rings 74 surrounding the active region 22. The mesa rings 72 have a second width w2, which may increase outwardly. That is, mesa rings 72 closer to the active region 22 may have a smaller width compared to mesa rings 72 farther from the active region 22. The guard rings 28 are provided as p-type implanted regions beneath the trench rings 74.

In the embodiment shown in FIGS. 9 and 10, the mesa width w2 of the mesa rings 72 is increased relative so that the innermost mesa rings 72 are spaced more widely than the active area mesa stripes 42, encouraging UIS breakdown to occur preferentially in the termination area 26 rather than the active area 22. As with the previous embodiments, this may lead to UIS current preferentially flowing through the termination rings 28 rather than the silicided trenches 152 in the active area 22, thereby reducing chances of hotspot failure.

In some embodiments, the mesa width w2 of the mesa rings 72 may be about 0.1 micron larger than an optimum mesa width needed for a desired blocking voltage rating to encourage UIS breakdown in the edge termination region 26 rather than in the active region 22. In some embodiments, the mesa width w2 of the mesa rings 72 may be about 0.2 micron larger than an optimum mesa width needed for a desired blocking voltage rating.

Moreover, in some embodiments, the semiconductor device 100D may have less than an optimum number of mesa rings needed for a desired blocking voltage rating to encourage UIS breakdown in the edge termination region 26 rather than in the active region 22. For example, in some embodiments, the semiconductor device 100D may include about 80% of the optimum number of mesa rings needed for a desired blocking voltage, and in some embodiments about 75% of the optimum number of mesa rings needed for a desired blocking voltage.

The typical spacing between implanted regions 76, 82 in the termination region 26 is about 0.6 microns to about 0.8 microns and is determined by the desired blocking voltage of the device 100D. According to some embodiments spacing of the implanted regions 76, 82 in the termination region 26 is made larger than 0.8 microns, with the termination rings 28 being spaced more widely apart farther from the active region. Both the spacing of the implanted regions 76, 82 that form the termination rings 28 and the rate of increase of ring spacing may be increased in a direction away from the active region 22.

In some embodiments, the spacing between implanted regions 76, 82 in the termination region 26 may be about 1% to 20% larger than the spacing of implanted regions 76, 82 in the active region 22. In further embodiments, the spacing between implanted regions 76, 82 in the termination region 26 may be about 5% to 15% larger than the spacing of implanted regions 76, 82 in the active region 22. In further embodiments, the spacing between implanted regions 76, 82 in the termination region 26 may be about 8% to 12% larger than the spacing of implanted regions 76, 82 in the active region 22.

The inventive concepts have been described above with reference to the accompanying drawings, in which embodiments are shown. The inventive concepts may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device comprising:
an active region comprising first and second mesa stripes and a trench between the mesa stripes, wherein the trench has a first width between the first and second mesa stripes near a central portion of the first and second mesa stripes and a second width between the first and second mesa stripes near end portions of the first and second mesa stripes, wherein the second width is less than the first width.

2. The semiconductor device of claim 1, wherein the first mesa stripe has a first width near the central portion of the first mesa stripe and a second width near the end portions of the first mesa stripe, wherein the second width is greater than the first width.

3. The semiconductor device of claim 2, wherein the first mesa stripe increases in width from the first width to the second width near the end portions of the first mesa stripe.

4. The semiconductor device of claim 3, wherein the first mesa stripe increases in width linearly from the first width to the second width near the end portions of the first mesa stripe.

5. The semiconductor device of claim 1, wherein the trench tapers in width from the first width to the second width near the end portions of the first and second mesa stripes.

6. The semiconductor device of claim 1, wherein the end portions of the first and second mesa stripes are separated from the central portions of the first and second mesa stripes by second trenches.

7. The semiconductor device of claim 6, further comprising a source metallization, wherein the source metallization contacts the central portions of the first and second mesa stripes and does not contact the end portions of the first and second mesa stripes.

8. The semiconductor device of claim 1, wherein the central portions of the first and second mesa stripes have a first channel doping and the end portions of the first and second mesas have a second channel doping, wherein the second channel doping is greater than the first channel doping.

9. The semiconductor device of claim 8, wherein the first and second mesa stripes comprise sidewall gate regions having a first conductivity type and channel regions between the sidewall gate regions, wherein the channel regions have the first channel doping in central portions of the mesa stripes and the second channel doping in the end portions of the mesa stripes.

10. The semiconductor device of claim 8, wherein the second channel doping is selected to preferentially induce unclamped inductive switching (UIS) breakdown near the end portions of the mesa stripes before UIS breakdown occurs near the central portions of the mesa stripes under voltage blocking conditions.

11. A semiconductor device comprising:
an active region comprising first and second mesa stripes and a first trench between the mesa stripes, wherein the first trench has a first width between the first and second mesa stripes; and
first and second dummy mesas adjacent respective first and second ends of the first and second mesa stripes, wherein the first and second dummy mesas define a second trench between the first and second dummy mesas, wherein the second trench has a second width between the first and second dummy mesas that is less than the first width.

12. The semiconductor device of claim 11, wherein the first and second mesa stripes each have a first width, and wherein the first and second dummy mesas each have a second width that is greater than the first width.

13. The semiconductor device of claim 11, further comprising a source metallization, wherein the source metallization contacts the first and second mesa stripes and does not contact the dummy mesas.

14. The semiconductor device of claim 11, wherein the first and second mesa stripes have a first channel doping and the first and second dummy mesas have a second channel doping, wherein the second channel doping is greater than the first channel doping.

15. The semiconductor device of claim 14, wherein the first and second mesa stripes and the first and second dummy mesas comprise sidewall gate regions having a first conductivity type and have channel regions having a second conductivity type between the sidewall gate regions, wherein the channel regions in the first and second mesa stripes have the first channel doping in the channel regions thereof and the first and second dummy mesas have the second channel doping in the channel regions thereof.

16. The semiconductor device of claim 14, wherein the second channel doping is selected to preferentially induce unclamped inductive switching (UIS) breakdown near the end portions of the mesa stripes before UIS breakdown occurs near the central portions of the mesa stripes.

17. A semiconductor device comprising:
an active region comprising first and second mesa stripes and a trench between the mesa stripes; and
a channel doping in the first and second mesa stripes, wherein the channel doping is higher near end portions of the first and second mesa stripes than near central portions of the first and second mesa stripes.

18. The semiconductor device of claim 17, wherein the first and second mesa stripes comprise sidewall gate regions having a first conductivity type and channel regions between the sidewall gate regions, wherein the channel regions have the first channel doping in central portions of the mesa stripes and the second channel doping in the end portions of the mesa stripes.

19. The semiconductor device of claim 17, wherein the second channel doping is selected to preferentially induce unclamped inductive switching (UIS) breakdown near the end portions of the mesa stripes before UIS breakdown occurs near the central portions of the mesa stripes under voltage blocking conditions.

20. A semiconductor device, comprising:
an active region comprising a plurality of alternating mesa stripes and trenches, wherein each of the mesa stripes extends in a first direction and has a width in a second direction that is perpendicular to the first direction; and
an edge termination region adjacent to the active region, wherein the edge termination region comprises a plurality of alternating mesa rings and trench rings;
wherein a width of a first mesa ring in the edge termination region is larger than the width of the mesa stripes.

21. The semiconductor device of claim 20, wherein the width of the first mesa ring is selected to preferentially induce unclamped inductive switching (UIS) breakdown near the first mesa ring before UIS breakdown occurs near the mesa stripes under voltage blocking conditions.

22. The semiconductor device of claim 20, wherein the width of the first mesa ring in the edge termination region is about 1% to about 20% larger than the width of the mesa stripes.

23. The semiconductor device of claim 20, wherein the width of the first mesa ring in the edge termination region is about 5% to about 15% larger than the width of the mesa stripes.

24. The semiconductor device of claim 20, wherein the width of the first mesa ring in the edge termination region is about 8% to about 12% larger than the width of the mesa stripes.

25. The semiconductor device of claim 20, wherein the semiconductor device comprises a vertical junction field effect transistor, and wherein the plurality of mesa stripes and trenches are formed in a semiconductor layer having a first conductivity type, the plurality of mesas comprising sidewall gate regions having a second conductivity type in sidewalls of the plurality of mesas and first conductivity type channel regions between the sidewall gate regions, the semiconductor device further comprising second conductivity type gate contact regions beneath the plurality of trenches and second conductivity type guard rings beneath the trench rings.

26. The semiconductor device of claim 22, wherein a spacing between the guard rings in the edge termination region is about 0.1 microns larger than an optimum guard ring spacing needed for a desired blocking voltage.

27. The semiconductor device of claim 22, wherein a spacing between the guard rings in the edge termination region is about 0.2 microns larger than an optimum guard ring spacing needed for a desired blocking voltage.
